(19) United States
(12) Patent Application Publication
(10) Pub. No.: US 2026/0182110 A1
(43) Pub. Date: Jun. 25, 2026

(54) DISPLAY DEVICE

(71) Applicant: LG Display Co., Ltd., Seoul (KR)

(72) Inventors: Sung-Woo JUN, Paju-si (KR); Dong-Min JANG, Paju-si (KR); Kwang-Il CHOI, Paju-si (KR)

(73) Assignee: LG Display Co., Ltd., Seoul (KR)

(21) Appl. No.: 19/194,915

(22) Filed: Apr. 30, 2025

(30) Foreign Application Priority Data
Dec. 20, 2024 (KR) 10-2024-0192121

(51) Int. Cl. H10H 29/41; G06F 3/041; H10H 29/49

(52) U.S. Cl. CPC H10H 29/41; G06F 3/041; H10H 29/49

(57) ABSTRACT

A display device in an example includes a substrate having a plurality of subpixels, a thin film transistor in each of the plurality of subpixels, at least one planarizing layer on the thin film transistor, a plurality of signal lines on the at least one planarizing layer, a first insulating layer between the plurality of signal lines, and a light emitting diode in each of the plurality of subpixels. A thickness of the first insulating layer is smaller than a thickness of the plurality of signal lines such that a top surface of the plurality of signal lines protrudes from a top surface of the first insulating layer.

### CROSS REFERENCE TO RELATED APPLICATIONS

This application claims priority to Korean Patent Application No. 10-2024-0192121, filed in the Republic of Korea on Dec. 20, 2024, the entire contents of which is hereby expressly incorporated by reference into the present application.

### BACKGROUND OF THE DISCLOSURE

### Field

The present disclosure relates to a display device, and more particularly, to a display device where an insulating layer is planarized.

### Discussion of Related Art

Recently, as a need for multimedia technology increases, an importance of a display device has increased. As a result, a flat panel display such as a liquid crystal display (LCD), a plasma display panel (PDP) and an organic light emitting diode (OLED) display has been commercialized. Among various flat panel displays, an OLED display device has been widely used because of its high response speed, high luminance and wide viewing angle.

Thin film transistors, electrodes and signal lines are disposed in each of the subpixels of the OLED display device, and an organic emitting element emits a light to display an image.

However, since the electrodes and the signal lines are formed to have a predetermined thickness, an insulating layer over the electrodes and the signal lines has a step difference due to the predetermined thickness. Specifically, when the step difference is formed in a planarizing layer where an anode is disposed, the anode on the planarizing layer can also have a step difference. When an external light reflects on the anode, the step difference of the anode can cause deterioration in a reflection visibility and a user can recognize such reflected light.

In some situations, the step difference can be alleviated by forming a plurality of insulating layers or increasing the thickness of the insulating layer. However, the plurality of insulating layers and the insulating layer having the increased thickness can cause limitations such as an increase in the thickness of the display device, an increase in the fabrication process steps, an increase in fabrication cost, an increase in pixel shrinkage, etc.

### SUMMARY OF THE DISCLOSURE

Accordingly, the present disclosure is directed to a display device that substantially obviates one or more of the problems due to limitations and disadvantages of the related art.

An object of the present disclosure is to provide a display device where deterioration in a reflection visibility due to a step difference of an anode is prevented, avoided or minimized.

Additional features and advantages of the disclosure will be set forth in the description which follows, and in part will be apparent from the description, or can be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device in some embodiments can include a substrate having a plurality of subpixels, a thin film transistor in each of the plurality of subpixels, at least one planarizing layer on the thin film transistor, a plurality of signal lines on the at least one planarizing layer, a first insulating layer between the plurality of signal lines, and a light emitting diode in each of the plurality of subpixels, wherein a thickness of the first insulating layer is smaller than a thickness of the plurality of signal lines such that a top surface of the plurality of signal lines protrudes from a top surface of the first insulating layer.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the disclosure, illustrate embodiments of the disclosure and together with the description serve to explain the principles of the disclosure. In the drawings:

FIG. 1 is a view showing a display device according to a first embodiment of the present disclosure;

FIG. 2 is a view showing a subpixel of a display device according to the first embodiment of the present disclosure;

FIG. 3 is a circuit diagram showing a subpixel of a display device according to the first embodiment of the present disclosure;

FIG. 4 is a cross-sectional view showing a display device according to the first embodiment of the present disclosure;

FIG. 5 is an example of a magnified view of A region of FIG. 4;

FIGS. 6A to 6D are cross-sectional views showing a method of fabricating a display device according to the first embodiment of the present disclosure;

FIG. 7 is a cross-sectional view showing a display device according to a second embodiment of the present disclosure; and

FIG. 8 is a cross-sectional view showing a display device according to a third embodiment of the present disclosure.

### DETAILED DESCRIPTION OF THE EMBODIMENTS

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure can be sufficiently thorough and complete to assist those skilled in the art to fully understand the scope of the present disclosure.

The shapes, sizes, ratios, angles, numbers, and the like, which are illustrated in the drawings to describe various embodiments of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration can unnecessarily obscure a feature or embodiment of the present disclosure, a detailed description of such known function or configuration can be omitted or a brief description can be provided.

Where the terms “comprise,” “have,” “include,” and the like are used, one or more other elements can be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third layer or element can be interposed therebetween.

Although the terms “first,” “second,” A, B, (a), (b), and the like can be used herein to refer to various elements, these elements should not be interpreted to be limited by these terms as they are not used to define a particular order or precedence. These terms are only used to distinguish one element from another and may not define order or sequence. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” can include all combinations of two or more of the first, second and third elements as well as the first, second or third element.

The term “display device” can include a display device in a narrow sense such as liquid crystal module (LCM), an organic light emitting diode (OLED) module and a quantum dot (QD) module including a display panel and a driving unit (i.e., driving circuit) for driving the display panel. In addition, the term “display device” can include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure can include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit can be expressed as “a display device”, and an electronic apparatus of a complete product including the LCM, the OLED module and the QD module can be expressed as “a set device.” For example, a display device in a narrow sense can include a display panel of a liquid crystal, an organic light emitting diode and a quantum dot and a source printed circuit board (PCB) of a control unit for driving the display panel, and a set device can further include a set PCB of a set control unit electrically connected to the source PCB for controlling the entire set device.

The display panel of the present disclosure can include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

The elements of the display panel and display device according to the embodiments of the present disclosure can include circuits, modules, parts, units, elements, or combinations thereof.

For example, when the display panel is an organic light emitting diode display panel, the display panel can include a plurality of gate lines, a plurality of data lines and a subpixel in a crossing region of the plurality of gate lines and the plurality of data lines. The display panel can include an array having a thin film transistor of an element for selectively applying a voltage to each subpixel, an emitting element layer on the array and an encapsulating substrate or an encapsulation part covering the emitting element layer. The encapsulation part can protect the thin film transistor and the emitting element layer from an external impact and can prevent or at least reduce penetration of a moisture or an oxygen into the emitting element layer. In addition, a layer on the array can include an inorganic light emitting layer, for example, a nano-sized material layer or a quantum dot.

The thin film transistor of the present disclosure can include one of an oxide thin film transistor, an amorphous silicon thin film transistor, a low temperature polycrystalline silicon thin film transistor.

Features of various embodiments of the present disclosure can be partially or entirely coupled to or combined with each other. They can be linked and operated technically in various ways as those skilled in the art can sufficiently understand. The embodiments can be carried out independently of or in association with each other in various combinations. Further, the term “can” fully encompasses all the meanings and coverages of the term “may” and vice versa.

Hereinafter, a display device according to various embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings. All the components of each display device according to all embodiments of the present disclosure are operatively coupled and configured.

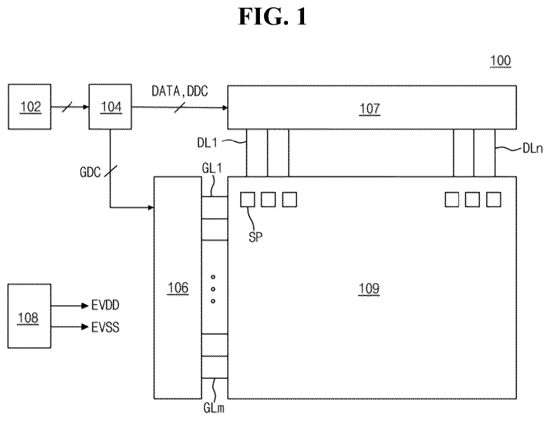

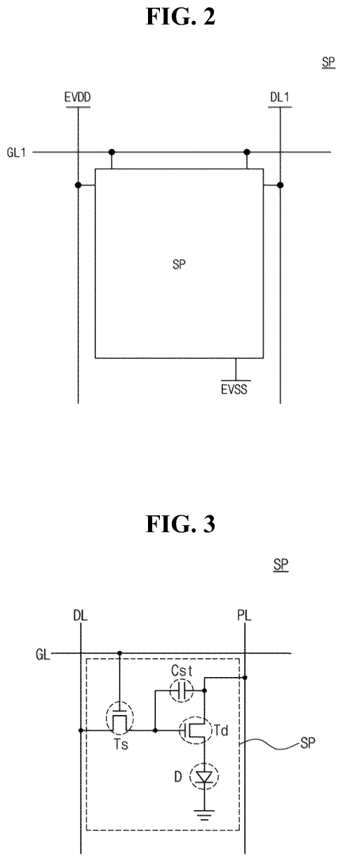

FIG. 1 is a view showing a display device according to a first embodiment of the present disclosure, and FIG. 2 is a view showing a subpixel of a display device according to the first embodiment of the present disclosure.

Referring to FIG. 1, a display device 100 according to the first embodiment of the present disclosure includes an image processing circuit (or image processor) 102, a timing controlling circuit (or timing controller) 104, a gate driving circuit (or gate driver) 106, a data driving circuit (or data driver) 107, a power supplying circuit (or power supply) 108 and a display panel 109.

The image processing circuit 102 outputs a plurality of timing signals for various units as well as an image signal supplied from an exterior. For example, the plurality of timing signals can include a data enable signal, a vertical synchronization signal, a horizontal synchronization signal and a clock signal.

The timing controlling circuit 104 receives the image signal and the plurality of timing signals from the image processing circuit 102. The timing controlling circuit 104 generates an image data DATA, a gate control signal GDC and a data control signal DDC using the image signal and the plurality of timing signals. The timing controlling circuit 104 transmits the gate control signal GDC to the gate driving circuit 106 and transmits the image data and the data control signal DDC to the data driving circuit 107.

The gate driving circuit 106 generates a gate signal (a gate voltage, a scan signal) using the gate control signal GDC transmitted from the timing controlling circuit 104 and applies the gate signal to a plurality of gate lines GL1 to GLm of the display panel 109, where m is a real number such as a positive integer. Although the gate driving circuit 106 can be formed as an integrated circuit (IC), it is not limited thereto.

The gate driving circuit 106 can have a gate-in-panel (GIP) type where various gate driving elements of the gate driving circuit 106 is disposed directly on a substrate of the display panel 109.

The data driving circuit 107 generates a data signal (a data voltage) using the data control signal DDC and the image data DATA transmitted from the timing controlling circuit 104 and applies the data signal to a plurality of data lines DL1 to DLn of the display panel 109, where n is a real number such as a positive integer. The data driving circuit 107 samples and latches the image data DATA of a digital type to output the data signal of an analog type based on a gamma reference voltage. Although the data driving circuit 107 can be formed as an integrated circuit (IC), it is not limited thereto.

The power supplying circuit 108 outputs a high level voltage Vdd and a low level voltage Vss. The power supplying circuit 108 supplies the high level voltage Vdd to the display panel 109 through a first power line EVDD and supplies the low level voltage Vss to the display panel 109 through a second power line EVSS. In addition, the high level voltage Vdd and the low level voltage Vss of the power supplying part 108 can be supplied to the gate driving circuit 106 or the data driving circuit 107 for driving.

The display panel 109 displays an image using the gate signal of the gate driving circuit 106, the data signal of the data driving circuit 107 and the high level voltage Vdd and the low level voltage Vss of the power supplying circuit 108.

The display panel 109 includes a plurality of subpixels SP, a plurality of gate lines GL1 to GLm and a plurality of data lines DL1 to DLn to display an image. The plurality of subpixels SP can include red, green and blue subpixels SP or white, red, green and blue subpixels SP, or other variations. The white, red, green and blue subpixels SP can have the same area as each other or can have different areas from each other.

Referring to FIG. 2, a single subpixel SP can be connected to the gate line GL1, the data line DL1, the first power line EVDD and the second power line EVSS. A driving method as well as a number of a transistor and a capacitor of the subpixel SP can be determined according to a structure of a subpixel circuit. For example, the subpixel SP can have a structure of 2T1C including two transistors and one capacitor. In another embodiment, the subpixel SP can have a structure of one of 3T1C, 4T1C, 5T1C, 6T1C, 7T1C, 3T2C, 4T2C, 5T2C, 6T2C, 7T2C and 8T2C. Each subpixel SP of the display panel 109 can have a configuration of the subpixel shown in FIGS. 2 and/or 3.

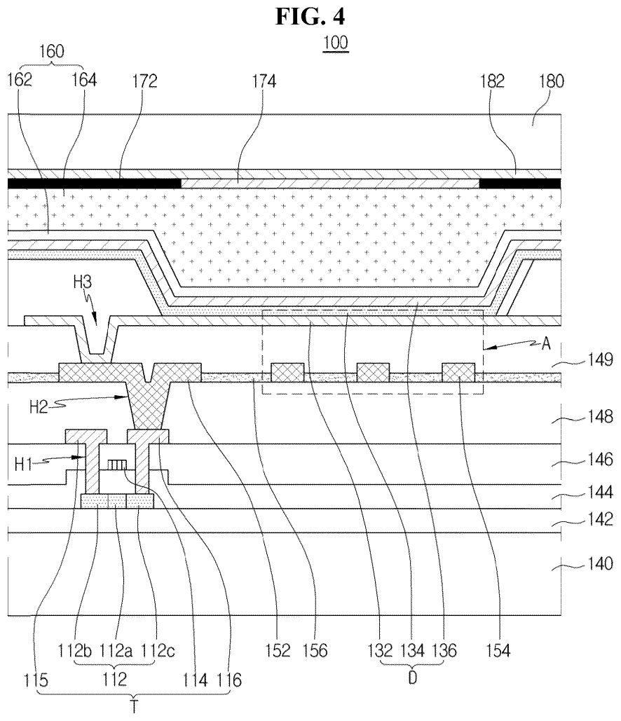

FIG. 3 is a circuit diagram showing a subpixel of a display device according to the first embodiment of the present disclosure.

Referring to FIG. 3, the display device 100 includes the gate line GL, the data line DL and the power line PL crossing each other to define the subpixel SP. A switching transistor Ts, a driving transistor Td, a storage capacitor Cst and a light emitting diode D are disposed in the subpixel SP.

The switching transistor Ts is connected to the gate line GL and the data line DL. The driving transistor Td and the storage capacitor Cst are connected between the switching transistor Ts and the power line PL. The light emitting diode D is connected to the driving transistor Td.

When the switching transistor Ts is turned on according to the gate signal of the gate line GL, the data signal of the data line DL is applied to a gate electrode of the driving transistor Td and one capacitor electrode of the storage capacitor Cst through the switching transistor Ts.

Since the driving transistor Td is turned on according to the data signal, a current proportional to the data signal flows from the power line PL to the light emitting diode D through the driving transistor Td and the light emitting diode D emits a light of a luminance proportional to the current flowing through the driving transistor Td.

The storage capacitor Cst is charged up with a voltage proportional to the data signal to keep a voltage of the gate electrode of the driving transistor Td constant for one frame.

Although the subpixel SP includes two transistors Td and Td and one capacitor Cst in the first embodiment of FIG. 3, the subpixel SP can include three or more transistors and two or more capacitors in another embodiment, or can have other configurations/structures.

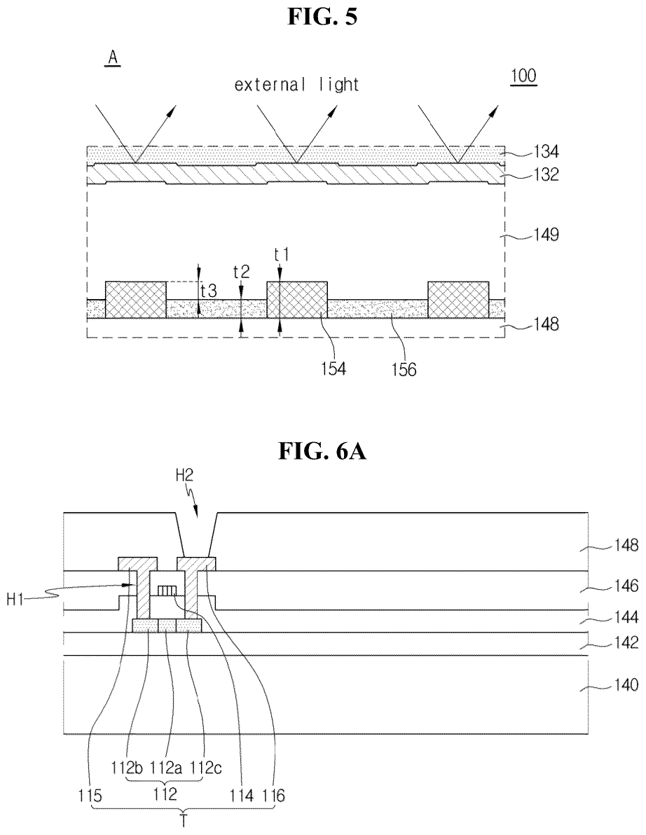

FIG. 4 is a cross-sectional view showing a display device according to the first embodiment of the present disclosure. Although the display device 100 includes a plurality of subpixels, one subpixel as an example is shown in FIG. 4 for illustration's convenience. For instance, each subpixel or at least one subpixel of the display device 100 of FIG. 4 can have the configuration shown in FIG. 4. The subpixel can include red, green and blue subpixels. Alternatively, the subpixel can include red, green, blue and white subpixels. For example, the subpixel can be a red subpixel, a green subpixel, a blue subpixel, or a white subpixel.

Referring to FIG. 4, a buffer layer 142 is disposed on a first substrate 140. The first substrate 140 can include a hard material such as a glass or a soft material such as a plastic material.

When the substrate 140 includes a plastic material, the first substrate 140 can include at least one of polyimide (PI), polymethylmethacrylate (PMMA), polyethylene terephthalate (PET), polyether sulfone (PES) and polycarbonate (PC), and it is not limited thereto.

When the first substrate 140 includes polyimide, the first substrate 140 can include a plurality of polyimide layers. Further, an inorganic layer can be disposed between the polyimide layers, and it is not limited thereto.

The buffer layer 142 can be disposed on the entire first substrate 140 to increase an adhesive strength between layers and the first substrate 140 and to block an alkali ingredient released from the first substrate 140. Further, the buffer layer 142 can delay diffusion of a moisture or an oxygen permeating the first substrate 140.

The buffer layer 142 can have a single layer or a multiple layer of an inorganic insulating material such as silicon nitride (SiNx) and silicon oxide (SiOx). When the buffer layer 142 has a multiple layer, a layer of silicon nitride (SiNx) and a layer of and silicon oxide (SiOx) can be alternated with each other. The buffer layer 142 can be omitted based on a kind and a material of the first substrate 140 and a structure and a type of the thin film transistor.

A thin film transistor T is disposed on the buffer layer 142. Although a driving thin film transistor among a plurality of thin film transistors in a display area (or active area) AA is shown in FIG. 4, the subpixel can include the other thin film transistor such as a switching thin film transistor. Further, although the thin film transistor T has a top gate structure in FIG. 4, the thin film transistor T can have the other structure such as a bottom gate structure or a dual gate structure.

The thin film transistor T includes a semiconductor layer 112 on the buffer layer 142, a gate insulating layer 144 on the semiconductor layer 112, a gate electrode 114 on the gate insulating layer 144, an interlayer insulating layer 146 on the gate electrode 114 and source and drain electrodes 115 and 116 on the interlayer insulating layer 146.

The semiconductor layer 112 can include a polycrystalline semiconductor material. For example, the polycrystalline semiconductor material can include polycrystalline silicon (e.g., low temperature polycrystalline silicon (LTPS)), and it is not limited thereto.

The semiconductor layer 112 can include an oxide semiconductor material. For example, the oxide semiconductor material can include one of indium gallium zinc oxide (IGZO), indium zinc oxide (IZO), indium gallium tin oxide (IGTO) and indium gallium oxide (IGO), and it is not limited thereto. The semiconductor layer 112 has a channel region 112a of an intrinsic material at a central portion thereof and source and drain regions 112b and 112c of a doped material at both sides of the channel region 112a.

The gate insulating layer 144 can have a single layer or a multiple layer of an inorganic insulating material such as silicon nitride (SiNx) and silicon oxide (SiOx), and it is not limited thereto.

The gate electrode 114 can include a metallic material. For example, the gate electrode 114 can have a single layer or a multiple layer of one of molybdenum (Mo), aluminum (Al), chromium (Cr), gold (Au), titanium (Ti), nickel (Ni), neodymium (Nd), copper (Cu) and an alloy thereof, and it is not limited thereto.

The interlayer insulating layer 146 can have a single layer or a multiple layer of an organic insulating material such as photoacryl or an inorganic insulating material such as silicon nitride (SiNx) and silicon oxide (SiOx). Further, the interlayer insulating layer 146 can have a multiple layer of an organic layer and an inorganic layer, and it is not limited thereto.

The source and drain electrodes 115 and 116 can have a single layer or a multiple layer of one of molybdenum (Mo), aluminum (Al), chromium (Cr), gold (Au), titanium (Ti), nickel (Ni), neodymium (Nd), copper (Cu) and an alloy thereof, and it is not limited thereto. The source and drain electrodes 115 and 116 can be connected to the source and drain regions 112b and 112c, respectively, of the semiconductor layer 112 through first contact holes H1 in the gate insulating layer 144 and the interlayer insulating layer 146.

A bottom shielding metal layer can be disposed on the first substrate 140 under the semiconductor layer 112. The bottom shielding metal layer can minimize or at least reduce a back channel phenomenon generated due to charges trapped in the first substrate 140 to prevent or at least reduce a residual image or deterioration of a transistor. The bottom shield metal layer can have a single layer or a multiple layer of one of titanium (Ti), molybdenum (Mo) and an alloy thereof, and it is not limited thereto.

A first planarizing layer 148 is disposed on the thin film transistor T over the entire first substrate 140. The first planarization layer 148 can include an organic insulating material such as photoacryl, and it is not limited thereto. Alternatively, the first planarizing layer 148 can have a multiple layer of an inorganic layer and an organic layer.

A second contact hole H2 is formed in the first planarizing layer 148 on the drain electrode 116 of the thin film transistor T, and the drain electrode 116 is exposed through the second contact hole H2. A connecting electrode 152 is disposed on the first planarizing layer 148 and is electrically connected to the drain electrode 116 of the thin film transistor T through the second contact hole H2.

The connecting electrode 152 can have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof or a transparent conductive material such as indium tin oxide (ITO) and indium zinc oxide (IZO), and it is not limited thereto.

A plurality of signal lines 154 where various signals applied to the display device 100 from an exterior are disposed on the first planarizing layer 148. For example, the plurality of signal lines 154 can include a high level voltage line for the high level voltage Vdd, a low level voltage line for the low level voltage Vss, a reference voltage line for a reference voltage and a sensing line for a sensing signal.

Although the plurality of signal lines 154 are disposed as an example in the subpixel in the first embodiment, the plurality of signal lines 154 can be disposed in a non-display area where an image is not displayed outside a display area where an image is displayed in another embodiment.

Although the plurality of signal lines 154 include the same material as the connecting electrode 152 in the first embodiment, the plurality of signal lines 154 can include a material different from a material of the connecting electrode 152 in another embodiment.

An insulating layer 156 is disposed between the plurality of signal lines 154 on the first planarizing layer 148. Since a thickness of the insulating layer 156 is smaller than a thickness of each of the plurality of signal lines 154, the plurality of signal lines 154 protrude upwardly from a top surface of the insulating layer 156.

Since a height difference between the insulating layer 156 and each of the plurality of signal lines 154 is smaller than a height difference between the first planarizing layer 148 and each of the plurality of signal lines 154, a step difference of the plurality of signal lines 154 is reduced due to the insulating layer 156. As a result, the insulating layer 156 can be referred to as a step difference reducing layer or a step difference alleviating layer for reducing or alleviating the step difference of the plurality of signal lines 154.

The insulating layer 156 can include an inorganic insulating material such as silicon oxide (SiOx) and silicon nitride (SiNx), and it is not limited thereto. The insulating layer 156 can have a single layer, and it is not limited thereto. For example, the insulating layer 156 can have a multiple layer according to a thickness of the plurality of signal lines 154.

Although the insulating layer 156 is disposed as an example over the entire first substrate 140 in the first embodiment, the insulating layer 156 can be disposed only between the plurality of signal lines 154.

A second planarizing layer 149 is disposed on the connecting electrode 152, the plurality of signal lines 154 and the insulating layer 156. Although the second planarizing layer 149 exemplarily includes the same material as the first planarizing layer 148 in the first embodiment, the second planarizing layer 149 can include different materials from the first planarizing layer 148 in another embodiment. For example, the second planarizing layer 149 can include an organic insulating material such as photoacryl, and it is not limited thereto. Alternatively, the second planarizing layer 149 can have a multiple layer of an inorganic insulating material and an organic insulating material.

A light emitting diode D is disposed on the second planarizing layer 149 in the emission area. The light emitting diode D includes a first electrode 132, an emitting layer 134 and a second electrode 136.

The first electrode 132 is disposed on the second planarizing layer 149 to be electrically connected to the connecting electrode 152 through a third contact hole H3 in the second planarizing layer 149. The first electrode 132 is electrically connected to the drain electrode 116 of the thin film transistor T through the connecting electrode 152.

Since a layer for planarization has a multiple layer of the first and second planarizing layers 148 and 149, the electrodes and the signal lines can be disposed between the first and second planarizing layers 148 and 149 in a cross-sectional view. As a result, a degree of integration of the electrodes and the signal lines is improved, and an area for the electrodes and the signal lines in the subpixel is reduced to obtain the display device 100 of a relatively high resolution.

The first electrode 132 can include at least one of silver (Ag), aluminum (Al), gold (Au), molybdenum (Mo), tungsten (W), chromium (Cr) and an alloy thereof. Alternatively, the first electrode 132 can include a transparent conductive material such as indium tin oxide (ITO) and indium zinc oxide (IZO).

A bank layer BNK is disposed in a border region between the adjacent subpixels on the second planarizing layer 150. The bank layer BNK can be a kind of wall in a boundary region of each subpixel and defining the subpixel. The bank layer BNK can prevent a mixture of lights of various colors emitted from adjacent subpixels.

The bank layer BNK can include at least one of an inorganic insulating material such as silicon nitride (SiNx) and silicon oxide (SiOx), an organic insulating material such as benzocyclobutene (BCB), acrylic resin, epoxy resin, phenolic resin, polyamide resin and polyimide resin and a photosensitive material including a black pigment, and it is not limited thereto.

An emitting layer 134 is disposed on the first electrode 132 in an emission area and can extend toward a non-emission area.

The emitting layer 134 can include a red emitting layer emitting a red colored light in a red subpixel, a green emitting layer emitting a green colored light in a green subpixel and a blue emitting layer emitting a blue colored light in a blue subpixel. For example, the emitting layer 134 can include an organic emitting layer or an inorganic emitting layer such as a nano-sized material layer, a quantum dot layer, a micro LED emitting layer and a mini LED emitting layer, and it is not limited thereto.

The emitting layer 134 can include an emitting material layer, an electron injecting layer injecting an electron, a hole injecting layer injecting a hole, an electron transporting layer transporting an electron, a hole blocking layer blocking a hole, an electron blocking layer blocking an electron and a hole transporting layer transporting a hole, and it is not limited thereto.

The second electrode 136 is disposed on the emitting layer 134. The second electrode 136 can have a single layer or a multiple layer of a metallic material or an alloy of metallic materials. Alternatively, the second electrode 136 can include a transparent conductive material such as indium tin oxide (ITO) and indium zinc oxide (IZO), and it is not limited thereto.

When the display device 100 has a top emission type, the second electrode 136 can include a half transmissive conductive material transmitting a light. For example, the second electrode 136 can include at least one of alloys of LiF/Al, CsF/Al, Mg:Ag, Ca/Ag, Ca:Ag, LiF/Mg:Ag, LiF/Ca/Ag and LiF/Ca:Ag.

The light emitting diode D can have a tandem structure. The tandem structure can include a plurality of emitting layers and a charge generating layer between the plurality of emitting layers. The charge generating layer for adjusting a charge balance of the plurality of emitting layers can have a multiple layer including first and second charge generating layers. The charge generating layer can include a negative (N) type charge generating layer and a positive (P) type charge generating layer. For example, the charge generating layer can include an emitting layer doped with an alkali metal such as lithium (Li), sodium (Na), potassium (K) and cesium (Cs) or an alkali earth metal such as magnesium (Mg), strontium (Sr), barium (Ba) and radium (Ra), and it is not limited thereto.

An encapsulating layer 160 is disposed on the light emitting diode D to encapsulate the light emitting diode D. When the light emitting diode D is exposed to a moisture or an oxygen, a pixel shrinkage phenomenon where an emission area is reduced or deterioration of a dark spot in the emission area can occur. Further, a moisture or an oxygen can oxidize the electrode of a metallic material. The encapsulating layer 160 blocks permeation of a moisture or an oxygen from an exterior to prevent or at least reduce deterioration of the light emitting diode D and the electrodes.

Although the encapsulating layer 160 has a double layer of first and second encapsulating layers 162 and 164 in the first embodiment, the encapsulating layer 160 can have a triple layer or a quadruple layer in another embodiment.

The first encapsulating layer 162 can include an inorganic material such as silicon oxide (SiOx), silicon oxynitride (SiON) and silicon nitride (SiNx), and it is not limited thereto. The second encapsulating layer 164 can include an organic material such as acrylic resin, epoxy resin, polyimide (PI), polyethylene (PE) and silicon oxycarbide (SiOC), and it is not limited thereto.

The first encapsulating layer 162 of an inorganic material can block permeation of a moisture or an oxygen, and the second encapsulating layer 164 can planarize a surface of the first encapsulating layer 162 and can prevent a crack of the encapsulating layer 160 due to an external force.

A black matrix 172 and a color filter layer 174 are disposed on the encapsulating layer 160.

The black matrix 172 is disposed in the non-emission area (e.g., an area between the subpixels), where an image is not displayed and the thin film transistor T is disposed. As a result, the black matrix 172 blocks a light passing through the non-emission area to prevent deterioration of a display quality. The black matrix 172 can include a metallic material such as chrome (Cr), a metallic oxide such as chrome oxide (CrO), or a resin including a black pigment.

The color filter layer 184 filters a light emitted from the light emitting diode D to transmit a portion of the light having a predetermined color. The color filter layer 184 can include a red color filter transmitting a red colored light, a green color filter transmitting a green colored light and a blue color filter transmitting a blue colored light.

A second substrate 180 is disposed over the black matrix 172 and the color filter layer 184. The second substrate 180 can include a hard material such as a glass or a soft material such as a plastic material.

An overcoat layer 182 is disposed between the black matrix 172 and the color filter layer 174 and the second substrate 180. The overcoat layer 182 can have an inorganic layer, an organic layer or a multiple layer of an inorganic layer and an organic layer.

In the display device 100 according to the first embodiment of the present disclosure, the step difference of the plurality of signal lines 156 is alleviated by forming the insulating layer 156 between adjacent two of the plurality of signal lines 156 on the first planarizing layer 146. As a result, deterioration in the reflection visibility on the anode is prevented.

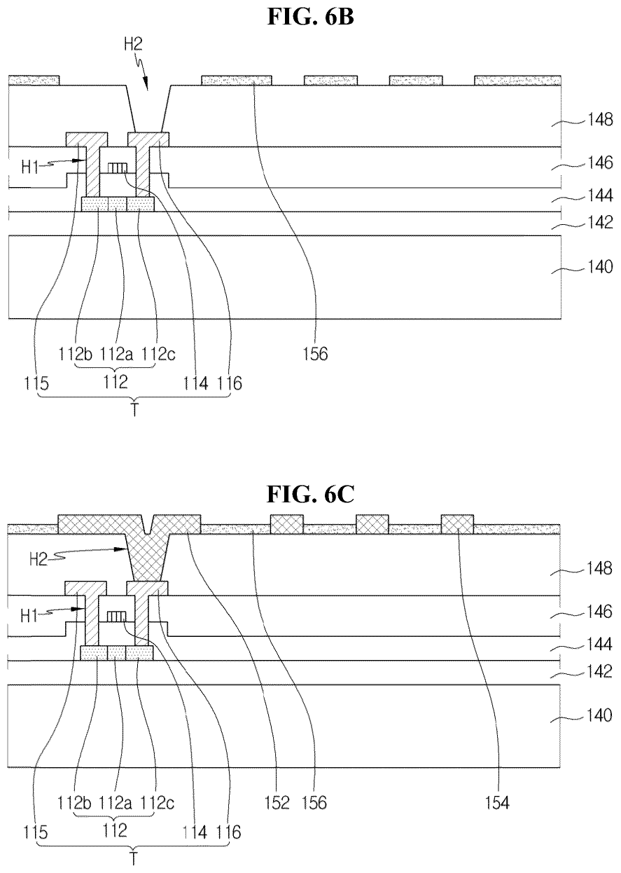

FIG. 5 is an example of a magnified view of A region of FIG. 4.

Referring to FIG. 5, the plurality of signal lines 154 are disposed on the first planarizing layer 148, and the insulating layer 156 is disposed between the plurality of signal lines 154. Since a thickness of the insulating layer 156 is smaller than a thickness of each of the plurality of signal lines 154, the plurality of signal lines 154 protrude upwardly from a top surface of the insulating layer 156.

For example, when each of the plurality of signal lines 154 has a first thickness t1 and the insulating layer 156 has a second thickness t2, a top surface of the insulating layer 156 and a top surface of each of the plurality of signal lines 154 have a step difference t3 (t3=t1−t2) smaller than the first thickness t1 (t3<t1). As a result, the step difference of the plurality of signal lines 154 is reduced by the second thickness of the insulating layer 156.

The second planarizing layer 149 is disposed on the plurality of signal lines 154 and the insulating layer 156, and the first electrode 132 and the emitting layer 134 are sequentially disposed on the second planarizing layer 149. The second planarizing layer 149 of an organic material can have a predetermined thickness.

In a display device according to a comparison example where the insulating layer 156 is not disposed between the plurality of signal lines 154, the plurality of signal lines 154 have a step difference the same as the first thickness t1 of each of the plurality of signal lines 154. In the display device 100 according to the first embodiment of the present disclosure, the plurality of signal lines 154 have a step difference t3 smaller than the first thickness due to the insulating layer 156.

When the plurality of signal lines 154 have a step difference, the second planarizing layer 149 on the plurality of signal lines 154 also has a step difference, and the first electrode 132 on the second planarizing layer 149 also has a step difference.

When the first electrode 132 includes a metallic material, an external light incident to the first electrode 132 is reflected by the first electrode 132 and is outputted to an exterior. Since the outputted light is recognized by an eye of a user, a display quality of the display device 100 can be deteriorated. However, since the color filter layer 182 is disposed over the light emitting diode D, the color filter layer 182 absorbs the light reflected by the first electrode 132 to prevent recognition of the outputted light.

As a result, in the display device 100 according to the first embodiment of the present disclosure, since the first electrode 132 does not have a step difference or has a small step difference due to the insulating layer 156, deterioration in the reflection visibility due to reflection of the external light at the step difference is prevented.

Specifically, deterioration in the reflection visibility due to reflection of the external light is prevented even when the second planarizing layer 149 has a thickness the same as the thickness of the second planarizing layer of the display device according to a comparison example or smaller than the thickness of the second planarizing layer of the display device according to a comparison example. As a result, a thickness of the display device 100 is reduced.

A method of fabricating the display device 100 according to embodiments of the present disclosure will be illustrated hereinafter with reference to drawings. All the operations/steps of the methods may be described below in some order or sequence, the present disclosure fully encompasses the methods where these steps/operations may be performed in different orders/sequences.

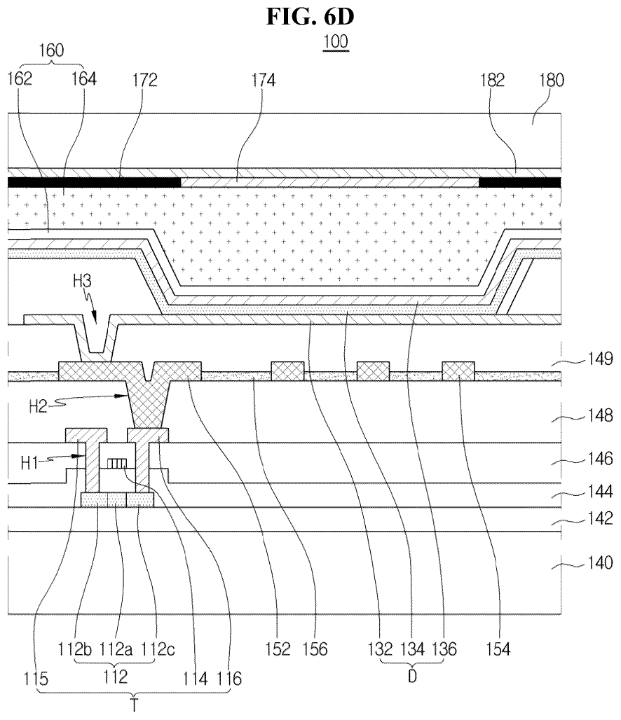

FIGS. 6A to 6D are cross-sectional views showing a method of fabricating a display device according to the first embodiment of the present disclosure.

Referring to FIG. 6A, the buffer layer 142 is formed on the entire first substrate 140. The first substrate 140 can include a hard material such as a glass or a soft material such as polyimide (PI), polymethylmethacrylate (PMMA), polyethylene terephthalate (PET), polyether sulfone (PES) and polycarbonate (PC). The buffer layer 142 can have a single layer or a multiple layer of an inorganic insulating material such as silicon nitride (SiNx) and silicon oxide (SiOx).

Next, the semiconductor layer 112 is formed on the buffer layer 142 by depositing and etching a polycrystalline semiconductor material such as polycrystalline silicon or an oxide semiconductor material such as indium gallium zinc oxide (IGZO), indium zinc oxide (IZO), indium gallium tin oxide (IGTO) and indium gallium oxide (IGO). Further, the channel region 112a, the source region 112b and the drain region 112c are formed by doping both sides of the semiconductor layer 112 with an impurity.

Next, after the gate insulating layer 144 is formed on the semiconductor layer 112 by depositing an inorganic insulating material such as silicon nitride (SiNx) and silicon oxide (SiOx), the gate electrode 114 is formed on the gate insulating layer 144 corresponding to the semiconductor layer 112 by depositing (e.g., sputtering) and etching (e.g., wet etching) a metallic material such as molybdenum (Mo), aluminum (Al), chromium (Cr), gold (Au), titanium (Ti), nickel (Ni), neodymium (Nd) and copper (Cu).

Next, the interlayer insulating layer 146 is formed on the gate electrode 114 by depositing an organic insulating material such as photoacryl or an inorganic insulating material such as silicon nitride (SiNx) and silicon oxide (SiOx), the first contact holes H1 are formed in the interlayer insulating layer 146 and the gate insulating layer 144 by etching (e.g., dry etching) the interlayer insulating layer 146 and the gate insulating layer 144 corresponding to the source region 112b and the drain region 112c of the semiconductor layer 112c.

Next, the source and drain electrodes 115 and 116 are formed on the interlayer insulating layer 146 by depositing (e.g., sputtering) and etching (e.g., wet etching) a metallic material such as molybdenum (Mo), aluminum (Al), chromium (Cr), gold (Au), titanium (Ti), nickel (Ni), neodymium (Nd) and copper (Cu). The source and drain electrodes 115 and 116 are connected to the source and drain regions 112b and 112c, respectively, of the semiconductor layer 112 through the first contact holes H1 to complete the thin film transistor T.

Next, after the first planarizing layer 148 is formed on the source and drain electrodes 115 and 116 by depositing an organic insulating material such as photoacryl or an inorganic insulating material such as silicon nitride (SiNx) and silicon oxide (SiOx), the second contact hole H2 is formed in the first planarizing layer 148 by etching (e.g., dry etching) the first planarizing layer 148 corresponding to the drain electrode 116.

Referring to FIG. 6B, after an inorganic insulating material layer is formed on the first planarizing layer 148 by depositing an inorganic insulating material such as silicon nitride (SiNx) and silicon oxide (SiOx), the insulating layer 154 is formed on the first planarizing layer 148 by etching the inorganic insulating material layer through a photolithographic process.

Referring to FIG. 6C, the connecting electrode 152 and the plurality of signal lines 154 are formed on the first planarizing layer 148 by depositing and etching a metallic material such as molybdenum (Mo), aluminum (Al), chromium (Cr), gold (Au), titanium (Ti), nickel (Ni), neodymium (Nd), copper (Cu) and an alloy thereof or a transparent conductive material such as indium tin oxide (ITO) and indium zinc oxide (IZO).

The connecting electrode 152 is electrically connected to the drain electrode 116 of the thin film transistor T through the second contact hole H2 in the first planarizing layer 148.

Referring to FIG. 6D, after the second planarizing layer 149 is formed on the connecting electrode 152, the plurality of signal lines 154 and the insulating layer 156 by depositing an organic insulating material such as photoacryl, the third contact hole H3 is formed in the second planarizing layer 149 by etching (dry etching) the second planarizing layer 149 corresponding to the connecting electrode 152.

Next, the first electrode 132 is formed on the second planarizing layer 149 by depositing (e.g., sputtering) and etching (wet etching) a metallic material such as silver (Ag), aluminum (Al), gold (Au), molybdenum (Mo), tungsten (W) and chromium (Cr). The first electrode 132 is electrically connected to the connecting electrode 152 through the third contact hole H3.

Next, the bank layer BNK is formed on the second planarizing layer 150 by depositing and etching (e.g., dry etching) an inorganic insulating material such as silicon nitride (SiNx) and silicon oxide (SiOx), an organic insulating material such as benzocyclobutene (BCB), acrylic resin, epoxy resin, phenolic resin, polyamide resin and polyimide resin and a photosensitive material including a black pigment.

Next, after the emitting layer 134 is formed on the first electrode 132 by evaporating or coating an emitting material, the second electrode 136 is formed on the emitting layer 134 by depositing a metallic material or a transparent conductive material such as indium tin oxide (ITO) and indium zinc oxide (IZO) to complete the light emitting diode D.

Next, after the first encapsulating layer 162 is formed on the second electrode 136 by depositing an inorganic material such as silicon oxide (SiOx), silicon oxynitride (SiON) and silicon nitride (SiNx), the second encapsulating layer 164 is formed on the first encapsulating layer 162 by depositing an organic material such as acrylic resin, epoxy resin, polyimide (PI), polyethylene (PE) and silicon oxycarbide (SiOC) to complete the encapsulating layer 160.

Next, after the black matrix 172 is formed on the second encapsulating layer 164 by depositing a metallic material such as chrome (Cr) or a metallic oxide such as chrome oxide (CrO) or coating a resin including a black pigment, the color filter layer 174 is formed on the second encapsulating layer 164 by coating a color resin.

Next, after the overcoat layer 182 is formed on the black matrix 172 and the color filter layer 174 by depositing an inorganic material and/or an organic material, the second substrate 180 including a hard material such as a glass or a soft material such as polyimide (PI), polymethylmethacrylate (PMMA), polyethylene terephthalate (PET), polyether sulfone (PES) and polycarbonate (PC) is disposed on the overcoat layer 182 to complete the display device 100.

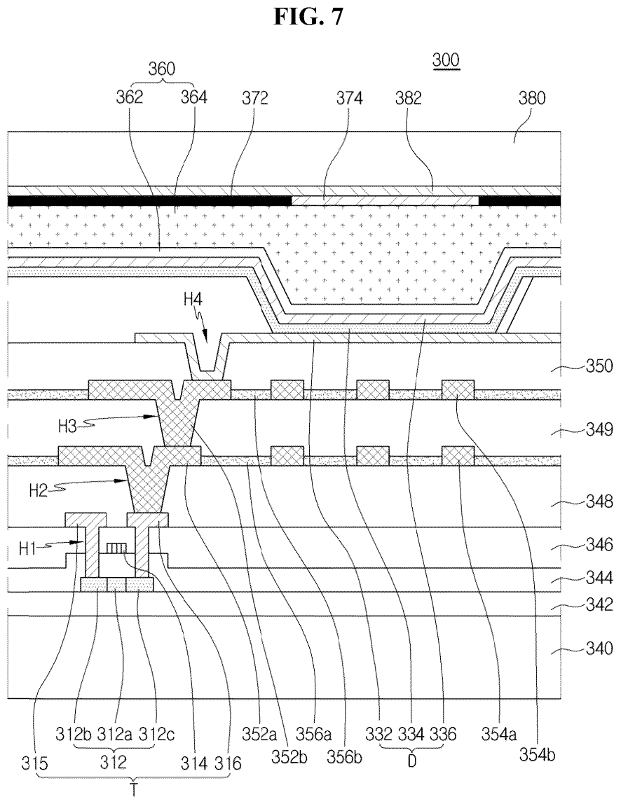

FIG. 7 is a cross-sectional view showing a display device according to a second embodiment of the present disclosure. Illustration on parts that are the same as those of the first embodiment will be omitted or may be briefly provided.

Referring to FIG. 7, a buffer layer 342 is disposed on a first substrate 340, and a thin film transistor T is disposed on the buffer layer 342.

The thin film transistor T includes a semiconductor layer 312 on the buffer layer 342, a gate insulating layer 344 on the semiconductor layer 312, a gate electrode 314 on the gate insulating layer 344, an interlayer insulating layer 346 on the gate electrode 314 and source and drain electrodes 315 and 316 on the interlayer insulating layer 346.

A first planarizing layer 348 is disposed on the thin film transistor T. The first planarization layer 348 can include an organic insulating material, and it is not limited thereto.

A first connecting electrode 352a and a plurality of first signal lines 354a are disposed on the first planarizing layer 348, and a first insulating layer 356a is disposed between the plurality of first signal lines 354a on the first planarizing layer 348.

The first connecting electrode 352a is electrically connected to the drain electrode 316 of the thin film transistor T through a second contact hole H2 in the first planarizing layer 348.

The first insulating layer 356a includes an inorganic insulating material. Since a thickness of the first insulating layer 356a is smaller than a thickness of the plurality of first signal lines 354a, a top surface of the plurality of first signal lines 354a protrudes from a top surface of the first insulating layer 356a. The first insulating layer 356a can be disposed over the entire first substrate 340 or can be disposed only between the plurality of first signal lines 354a.

Since the first insulating layer 356a is disposed between the plurality of first signal lines 354a, a step difference of the plurality of first signal lines 354a is reduced due to the first insulating layer 356a.

A second planarizing layer 349 is disposed on the first connecting electrode 352a, the plurality of first signal lines 354a and the first insulating layer 356a. The second planarization layer 349 can include an organic insulating material, and it is not limited thereto.

A second connecting electrode 352b and a plurality of second signal lines 354b are disposed on the second planarizing layer 349, and a second insulating layer 356b is disposed between the plurality of second signal lines 354b on the second planarizing layer 349.

The second connecting electrode 352b is electrically connected to the first connecting electrode 352a through a third contact hole H3 in the second planarizing layer 349.

The second insulating layer 356b includes an inorganic insulating material. Since a thickness of the second insulating layer 356b is smaller than a thickness of the plurality of second signal lines 354b, a top surface of the plurality of second signal lines 354b protrudes from a top surface of the second insulating layer 356b. The second insulating layer 356b can be disposed over the entire first substrate 340 or can be disposed only between the plurality of second signal lines 354b.

Since the second insulating layer 356b is disposed between the plurality of second signal lines 354b, a step difference of the plurality of second signal lines 354b is reduced due to the second insulating layer 356b.

Although the plurality of first signal lines 354a on the first planarizing layer 348 and the plurality of second signal lines 354b on the second planarizing layer 349 are disposed to be aligned to each other in the first embodiment, the plurality of first signal lines 354a and the plurality of second signal lines 354b can be disposed in different portions not to be aligned to each other in another embodiment.

A third planarizing layer 350 is disposed on the second connecting electrode 352b, the plurality of second signal lines 354b and the second insulating layer 356b. The third planarization layer 350 can include an organic insulating material, and it is not limited thereto.

A bank layer BNK is disposed in a border region between the adjacent subpixels on the third planarizing layer 350, and a light emitting diode D is disposed in an emission area of the subpixel between the bank layers BNK. The light emitting diode D includes a first electrode 332 on the third planarizing layer 350, an emitting layer 334 on the first electrode 332 and a second electrode 336 on the emitting layer 334.

An encapsulating layer 360 is disposed on the light emitting diode D. The encapsulating layer 360 includes a first encapsulating layer 362 of an inorganic material and a second encapsulating layer 364 of an organic material, and it is not limited thereto.

A black matrix 372 and a color filter layer 374 are disposed on the encapsulating layer 360, and an overcoat layer 382 and a second substrate 380 are sequentially disposed on the black matrix 372 and the color filter layer 374 to complete a display device 300 according to the second embodiment of the present disclosure.

In the display device 100 according to the first embodiment of the present disclosure of FIG. 4, the connecting electrode 152 and the plurality of signal lines 154 are disposed between the first and second planarizing layers 148 and 149. In the display device 300 according to the second embodiment of the present disclosure, the first connecting electrode 352a and the plurality of first signal lines 354a are disposed between the first and second planarizing layers 348 and 349, and the second connecting electrode 352b and the plurality of second signal lines 354b are disposed between the second and third planarizing layers 349 and 350.

Since the first insulating layer 356a is disposed between the plurality of first signal lines 354a and the second insulating layer 356b is disposed between the plurality of second signal lines 354b, the step difference due to the plurality of first signal lines 354a and the step difference due to the plurality of second signal lines 354b are reduced. As a result, the step difference of the second planarizing layer 349 on the plurality of first signal lines 354a and the step difference of the third planarizing layer 350 on the plurality of second signal lines 354b are reduced or removed. Accordingly, the step difference of the first electrode 332 on the third planarizing layer 350 is removed, and deterioration in a reflection visibility due to the step difference due to the first electrode 332 is prevented.

Although the first insulating layer 356a is disposed between the plurality of first signal lines 354a and the second insulating layer 356b is disposed between the plurality of second signal lines 354b in the second embodiment, the first insulating layer 356a between the plurality of first signal lines 354a is omitted and only the second insulating layer 356b is disposed between the plurality of second signal lines 354b in another embodiment.

In the display device 300 according to the second embodiment of the present disclosure, since the plurality of first signal lines 354a are disposed between the first and second planarizing layers 348 and 349 and the plurality of second signal lines 354b are disposed between the second and third planarizing layers 349 and 350, a number of signal lines per unit area increases as compared with the display device 100 according to the first embodiment of the present disclosure. As a result, an area of the subpixel is reduced to obtain the display device 300 of a relatively high resolution.

Further, since the first insulating layer 356a is disposed between the plurality of first signal lines 354a and the second insulating layer 356b is disposed between the plurality of second signal lines 354b, the step difference of the first electrode 332 of the light emitting diode D due to the plurality of first signal lines 354a and the plurality of second signal lines 354b is minimized, and deterioration in a reflection visibility due to the step difference due to the first electrode 332 is prevented.

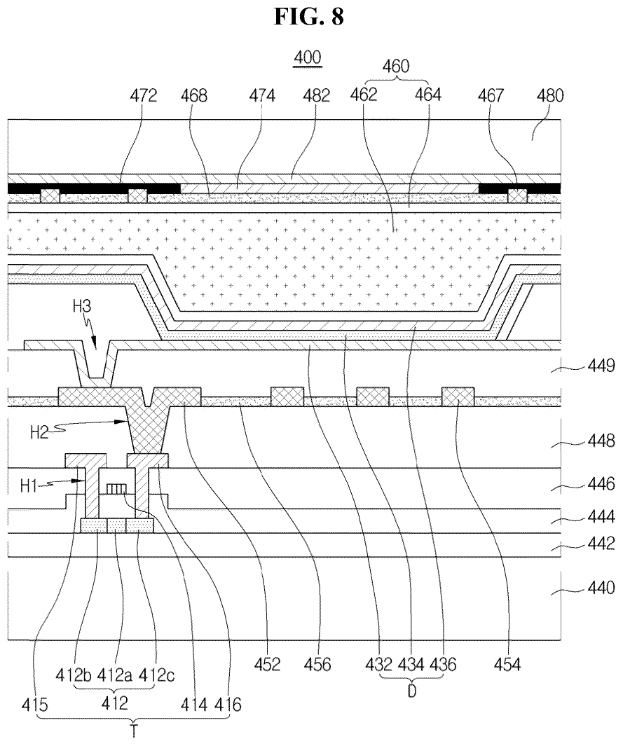

FIG. 8 is a cross-sectional view showing a display device according to a third embodiment of the present disclosure. Illustration on parts that are the same as those of the first embodiment will be omitted or may be briefly provided.

Referring to FIG. 8, a buffer layer 442 is disposed on a first substrate 440, and a thin film transistor T is disposed on the buffer layer 442.

The thin film transistor T includes a semiconductor layer 412 on the buffer layer 442, a gate insulating layer 444 on the semiconductor layer 412, a gate electrode 414 on the gate insulating layer 444, an interlayer insulating layer 446 on the gate electrode 414 and source and drain electrodes 415 and 416 on the interlayer insulating layer 446.

A first planarizing layer 448 is disposed on the thin film transistor T. The first planarization layer 448 can include an organic insulating material, and it is not limited thereto.

A connecting electrode 452 and a plurality of signal lines 454 are disposed on the first planarizing layer 448, and a first insulating layer 456 is disposed between the plurality of signal lines 454 on the planarizing layer 448.

The connecting electrode 452 is electrically connected to the drain electrode 416 of the thin film transistor T through a second contact hole H2 in the first planarizing layer 448.

The first insulating layer 456 includes an inorganic insulating material. Since a thickness of the first insulating layer 456 is smaller than a thickness of the plurality of signal lines 454, a top surface of the plurality of signal lines 454 protrudes from a top surface of the first insulating layer 456. The first insulating layer 456 can be disposed over the entire first substrate 440 or can be disposed only between the plurality of signal lines 454.

Since the a first insulating layer 456 is disposed between the plurality of signal lines 454, a step difference of the plurality of signal lines 454 is reduced due to the a first insulating layer 456.

A second planarizing layer 449 is disposed on the connecting electrode 452, the plurality of signal lines 454 and the first insulating layer 456. The second planarization layer 449 can include an organic insulating material, and it is not limited thereto.

A bank layer BNK is disposed in a border region between the adjacent subpixels on the second planarizing layer 449, and a light emitting diode D is disposed in an emission area of the subpixel between the bank layers BNK. The light emitting diode D includes a first electrode 432 on the second planarizing layer 449, an emitting layer 434 on the first electrode 432 and a second electrode 436 on the emitting layer 434.

An encapsulating layer 460 is disposed on the light emitting diode D. The encapsulating layer 460 includes a first encapsulating layer 462 of an inorganic material and a second encapsulating layer 464 of an organic material, and it is not limited thereto.

A plurality of touch lines 467 are disposed on the encapsulating layer 460. The plurality of touch lines 467 can include a touch electrode for sensing a touch, a touch driving line for transmitting a touch signal from a touch driving circuit to the display device 400 or a touch sensing line for outputting a touch signal from the display device 400 to a touch driving circuit.

A second insulating layer 468 is disposed between the plurality of touch lines 467 on the encapsulating layer 460. The second insulating layer 468 includes an inorganic insulating material such as silicon oxide (SiOx) and silicon nitride (SiNx), and it is not limited thereto. Since a thickness of the second insulating layer 468 is smaller than a thickness of the plurality of touch lines 467, a top surface of the plurality of touch lines 467 protrudes from a top surface of the second insulating layer 468. The second insulating layer 468 can be disposed over the entire first substrate 440 or can be disposed only between the plurality of touch lines 467.

The second insulating layer 468 and the plurality of touch lines 467 can be formed through a process the same as a process for forming the insulating layer 156 and the plurality of signal lines 154 of the first embodiment. For example, after the second insulating layer 468 exposing a portion of the encapsulating layer 460 is formed on the encapsulating layer 460 by depositing and etching an inorganic insulating material, the plurality of touch lines 467 are formed on the encapsulating layer 460 by depositing and etching a metallic material.

A black matrix 472 and a color filter layer 474 are disposed on the second insulating layer 458 and the plurality of touch lines 467, and an overcoat layer 482 and a second substrate 480 are sequentially disposed on the black matrix 472 and the color filter layer 474 to complete a display device 400 according to the third embodiment of the present disclosure.

In the display device 400 according to the third embodiment of the present disclosure, since the second insulating layer 468 having a thickness smaller than a thickness of the plurality of touch lines 467 is disposed between the plurality of touch lines 467, the step difference due to the plurality of touch lines 467 is reduced due to the second insulating layer 468.

Further, the encapsulating layer 460 includes the first encapsulating layer 462 of an inorganic material and the second encapsulating layer 464 of an organic material, and the plurality of touch lines 467 are disposed on the encapsulating layer 464.

In the process for forming the second insulating layer 468 and the plurality of touch lines 467, after the second insulating layer 468 is formed, the plurality of touch lines 467 are formed. As a result, when a metallic material layer is etched with an etching solution for the plurality of touch lines 467, the second insulating layer 468 blocks permeation of the etching solution to the second encapsulating layer 464.

When the second insulating layer 468 is omitted, the etching solution permeates the second encapsulating layer 464 to etch the second encapsulating layer 468, and the step difference of the plurality of touch lines 467 increases due to the etching of the second insulating layer 468.

In the display device 400 according to the third embodiment of the present disclosure, a relative height of the plurality of touch lines 467 is reduced and the etching of the second encapsulating layer 464 is prevented due to the second insulating layer 468. As a result, the step difference of the plurality of touch lines 467 is reduced.

The black matrix 472 on the plurality of touch lines 467 can have a predetermined thickness corresponding to a thickness of the second insulating layer 468. As a result, when the second insulating layer 468 is omitted, a thickness of the black matrix 472 on the plurality of touch lines 467 is reduced due to increase of the step difference of the plurality of touch lines 467.

The black matrix 472 includes an opaque metallic material such as chromium (Cr) and chromium oxide (CrOx) or a resin having a black pigment to block a light toward an unwanted region. When the thickness of the black matrix 472 on the plurality of touch lines 467 is reduced due to the step difference of the plurality of touch lines 467, the light from the plurality of touch lines 467 (e.g., an external light reflected on the plurality of touch lines 467) is not completely blocked by the black matrix 472 and is emitted to an exterior to be recognized by a user.

In the display device 400 according to the third embodiment of the present disclosure, a relative height of the plurality of touch lines 467 protruding from the top surface of the second insulating layer 468 is reduced due to the second insulating layer 468, and the etching of the second encapsulating layer 464 is prevented due to the second insulating layer. As a result, the step difference of the plurality of touch lines 467 is reduced, and deterioration in the reflection visibility due to reduction of the relative thickness of the black matrix 472 on the plurality of touch lines 467 is prevented.

Consequently, according to aspects of the present disclosure, since an insulating layer having a relatively small thickness is disposed between signal lines, a step difference due to the signal lines is reduced. As a result, a step difference of the anode is reduced, and deterioration in a reflection visibility due to the step difference of the anode is prevented, eliminated or minimized.

Further, according to aspects of the present disclosure, since deterioration in a reflection visibility is prevented, eliminated or prevented, a power consumption is reduced or minimized to obtain a low power consumption is obtained.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A display device, comprising:
a substrate including a plurality of subpixels;
a thin film transistor in each of the plurality of subpixels;
at least one planarizing layer on the thin film transistor;
a plurality of signal lines on the at least one planarizing layer;
a first insulating layer between the plurality of signal lines; and
a light emitting diode in each of the plurality of subpixels,
wherein a thickness of the first insulating layer is smaller than a thickness of the plurality of signal lines so that a top surface of the plurality of signal lines protrudes from a top surface of the first insulating layer.

2. The display device of claim 1, wherein the at least one planarizing layer comprises:
a first planarizing layer on the thin film transistor; and
a second planarizing layer on the first planarizing layer.

3. The display device of claim 2, wherein the plurality of signal lines are disposed on the first planarizing layer.

4. The display device of claim 3, further comprising a connecting electrode on the first planarizing layer,
wherein the connecting electrode is electrically connected to the thin film transistor through a first contact hole in the first planarizing layer and is electrically connected to the light emitting diode through a second contact hole in the second planarizing layer.

5. The display device of claim 1, wherein the at least one planarizing layer comprises:
a first planarizing layer on the thin film transistor;
a second planarizing layer on the first planarizing layer; and
a third planarizing layer on the second planarizing layer.

6. The display device of claim 5, wherein the plurality of signal lines comprise:
a plurality of first signal lines on the first planarizing layer; and
a plurality of second signal lines on the second planarizing layer.

7. The display device of claim 6, further comprising:
a first connecting electrode on the first planarizing layer, the first connecting electrode electrically connected to the thin film transistor through a first contact hole in the first planarizing layer; and
a second connecting electrode on the second planarizing layer, the second connecting electrode electrically connected to the first connecting electrode through a second contact hole in the second planarizing layer and electrically connected to the light emitting diode through a third contact hole in the third planarizing layer.

8. The display device of claim 7, wherein the first insulating layer is disposed between the plurality of first signal lines.

9. The display device of claim 8, further comprising a second insulating layer between the plurality of second signal lines.

10. The display device of claim 1, wherein the first insulating layer includes an inorganic insulating material.

11. The display device of claim 1, further comprising:
an encapsulating layer on the light emitting diode;
a plurality of touch lines on the encapsulating layer;
a second insulating layer between the plurality of touch lines; and
a black matrix and a color filter layer on the plurality of touch lines.

12. The display device of claim 11, wherein a thickness of the second insulating layer is smaller than a thickness of the plurality of touch lines so that a top surface of the plurality of touch lines protrudes from a top surface of the second insulating layer.

13. The display device of claim 11, wherein the second insulating layer includes an inorganic insulating material.

14. The display device of claim 1, wherein the plurality of signal lines include one or more signal lines among a high level voltage line for providing a high level voltage, a low level voltage line for providing a low level voltage, a reference voltage line for providing a reference voltage, and a sensing line for providing a sensing signal.

15. The display device of claim 1, further comprising a connecting electrode on the at least one planarizing layer,
wherein the connecting electrode includes a same material as the plurality of signal lines.

16. The display device of claim 1, wherein the plurality of signal lines are disposed in a display area of the plurality of subpixels.
